(19) United States
(12) Patent Application Publication
(10) Pub. No.: US 2025/0377382 A1
(43) Pub. Date: Dec. 11, 2025

(54) DIRECT-CURRENT CURRENT MEASUREMENT

(71) Applicant: MILWAUKEE ELECTRIC TOOL CORPORATION, Brookfield, WI (US)

(72) Inventors: Zhou Lu, Milwaukee, WI (US); Benjamin C. Tesch, Milwaukee, WI (US)

(21) Appl. No.: 19/227,165

(22) Filed: Jun. 3, 2025

Related U.S. Application Data
(60) Provisional application No. 63/656,918, filed on Jun. 6, 2024.

(51) Int. Cl. G01R 15/14; G01R 19/00; G01R 31/382

(52) U.S. Cl. CPC G01R 15/146; G01R 19/0092; G01R 31/382

(57) ABSTRACT

Embodiments described herein relate to a DC current measurement circuit, a method of DC current measurement and an electronic device including the DC current measurement circuit. The DC current measurement circuit includes a shunt resistor, an LPF, and an amplifier. The shunt resistor is electrically connected in a current path and configured to convert a current flowing through the current path to a voltage signal. The LPF is electrically connected to the shunt resistor and configured to receive the voltage signal from the shunt resistor and output a filtered voltage signal. The amplifier is connected to the LPF and configured to receive the filtered voltage signal and provide a measurement signal. The measurement signal provides a measurement of the current flowing through the current path.

### FIELD

Embodiments described herein relate to apparatus, circuit, and method for direct-current (DC) current measurement.

### SUMMARY

In some aspects, the techniques described herein relate to a direct-current (DC) current measurement circuit including: a shunt resistor electrically connected in a current path, a current flowing through the current path includes an alternating-current (AC) component; a low-pass filter (LPF) electrically connected across the shunt resistor and configured to filter a voltage signal across the shunt resistor and output a filtered voltage signal; and an amplifier electrically connected to the LPF and configured to receive the filtered voltage signal and output a measurement signal, the measurement signal provides a measurement of a DC component of the current.

In some aspects, the techniques described herein relate to an electronic device, including: a power converter electrically connected between a battery system and a load; and a direct-current (DC) current measurement circuit electrically connected in a current path of the power converter and including a resistor electrically connected in the current path, a current flowing through the current path includes an alternating-current (AC) component; a low-pass filter (LPF) electrically connected across the resistor and configured to filter a voltage signal across the shunt resistor and output a filtered voltage signal; and an amplifier electrically connected to the LPF and configured to amplify the filtered voltage signal and output a measurement signal.

In some aspects, the techniques described herein relate to a portable power source including: a battery system; a power converter electrically connected to the battery system; a direct-current (DC) current measurement circuit electrically connected in a current path of the power converter and including a resistor electrically connected in the current path, a current flowing through the current path includes an alternating-current (AC) component; a low-pass filter (LPF) electrically connected across the resistor and configured to filter a voltage signal across the shunt resistor and output a filtered voltage signal; and an amplifier electrically connected to the LPF and configured to amplify the filtered voltage signal and output a measurement signal.

One embodiment provides a DC current measurement circuit including a shunt resistor, an LPF, and an amplifier. The shunt resistor is electrically connected in a current path and configured to convert a current flowing through the current path to a voltage signal. The LPF is electrically connected to the shunt resistor and configured to receive the voltage signal from the shunt resistor and output a filtered voltage signal. The amplifier is connected to the LPF and configured to receive the filtered voltage signal and provide a measurement signal. The measurement signal provides a measurement of the current flowing through the current path.

Another embodiment provides a method for direct-current (DC) current measurement including converting, using a shunt resistor electrically connected in a current path, a current flowing through the current path to a voltage signal, filtering, using a low-pass filter (LPF) electrically connected to the shunt resistor, the voltage signal, and amplifying, using an amplifier electrically connected to the LPF, the voltage signal to provide a measurement signal. The measurement signal provides a measurement of the current flowing through the current path.

Yet another embodiment provides an electronic device including a power converter electrically connected between a battery system and a load, and a DC current measurement circuit electrically connected in a current path of the power converter. The DC current measurement circuit includes, a resistor, and LPF, and an amplifier. The resistor is electrically connected in the current path and configured to convert a current flowing through the current path to a voltage signal. The LPF is electrically connected to the resistor and configured to filter the voltage signal. The amplifier is electrically connected to the LPF and configured to amplify the filtered voltage signal.

Before any embodiments are explained in detail, it is to be understood that the embodiments are not limited in its application to the details of the configuration and arrangement of components set forth in the following description or illustrated in the accompanying drawings. The embodiments are capable of being practiced or of being carried out in various ways. Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings.

Unless the context of their usage unambiguously indicates otherwise, the articles “a,” “an,” and “the” should not be interpreted as meaning “one” or “only one.” Rather these articles should be interpreted as meaning “at least one” or “one or more.” Likewise, when the terms “the” or “said” are used to refer to a noun previously introduced by the indefinite article “a” or “an,” “the” and “said” mean “at least one” or “one or more” unless the usage unambiguously indicates otherwise.

In addition, it should be understood that embodiments may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic-based aspects may be implemented in software (e.g., stored on non-transitory computer-readable medium) executable by one or more processing units, such as a microprocessor and/or application specific integrated circuits (“ASICs”). As such, it should be noted that a plurality of hardware and software-based devices, as well as a plurality of different structural components, may be utilized to implement the embodiments. For example, “servers,” “computing devices,” “controllers,” “processors,” etc., described in the specification can include one or more processing units, one or more computer-readable medium modules, one or more input/output interfaces, and various connections (e.g., a system bus) connecting the components.

Relative terminology, such as, for example, “about,” “approximately,” “substantially,” etc., used in connection with a quantity or condition would be understood by those of ordinary skill to be inclusive of the stated value and has the meaning dictated by the context (e.g., the term includes at least the degree of error associated with the measurement accuracy, tolerances [e.g., manufacturing, assembly, use, etc.] associated with the particular value, etc.). Such terminology should also be considered as disclosing the range defined by the absolute values of the two endpoints. For example, the expression “from about 2 to about 4” also discloses the range “from 2 to 4”. The relative terminology may refer to plus or minus a percentage (e.g., 1%, 5%, 10%, or more) of an indicated value.

It should be understood that although certain drawings illustrate hardware and software located within particular devices, these depictions are for illustrative purposes only. Functionality described herein as being performed by one component may be performed by multiple components in a distributed manner. Likewise, functionality performed by multiple components may be consolidated and performed by a single component. In some embodiments, the illustrated components may be combined or divided into separate software, firmware and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable communication links. Similarly, a component described as performing particular functionality may also perform additional functionality not described herein. For example, a device or structure that is “configured” in a certain way is configured in at least that way but may also be configured in ways that are not explicitly listed.

Accordingly, in the claims, if an apparatus, method, or system is claimed, for example, as including a controller, control unit, electronic processor, computing device, logic element, module, memory module, communication channel or network, or other element configured in a certain manner, for example, to perform multiple functions, the claim or claim element should be interpreted as meaning one or more of such elements where any one of the one or more elements is configured as claimed, for example, to make any one or more of the recited multiple functions, such that the one or more elements, as a set, perform the multiple functions collectively.

Other aspects of the embodiments will become apparent by consideration of the detailed description and accompanying drawings.

### BRIEF DESCRIPTION OF THE DRAWINGS

FIG. 1 is a simplified block diagram of a DC current measurement circuit in accordance with some embodiments.

FIG. 2 is a simplified block diagram of an electronic device including the DC current measurement circuit of FIG. 1 in accordance with some embodiments.

FIG. 3A-3C are perspective views of example electrical devices including the DC current measurement circuit of FIG. 1 in accordance with some embodiments.

FIG. 4 is a simplified block diagram of a battery supplied flyback converter using the DC current measurement circuit of FIG. 1 in accordance with some embodiments.

FIG. 5 is a graph showing results of the DC current measurement circuit of FIG. 1 when used in the battery supplied flyback converter of FIG. 4 in accordance with some embodiments.

FIG. 6 is a simplified block diagram of DC-DC converter using the DC current measurement circuit of FIG. 1 in accordance with some embodiments.

FIG. 7 is a flowchart of a method for DC current measurement in accordance with some embodiments.

### DETAILED DESCRIPTION

Power tool devices and portable power supplies use various converter circuits, for example, DC to alternating-current (AC) converter, DC-DC converter, AC-AC converter, AC-DC converter, and their combinations. A transformer may be used to convert voltage at a first level to a second level that is desirable for use at an output of the converter. Transformers are typically used to boost or buck AC voltage. Undesired core saturation may occur in a transformer when a DC current component flows through the transformer with the AC current. Even a small amount of DC current may quickly result in core saturation. However, detecting small DC currents in a signal having a large AC component may be challenging.

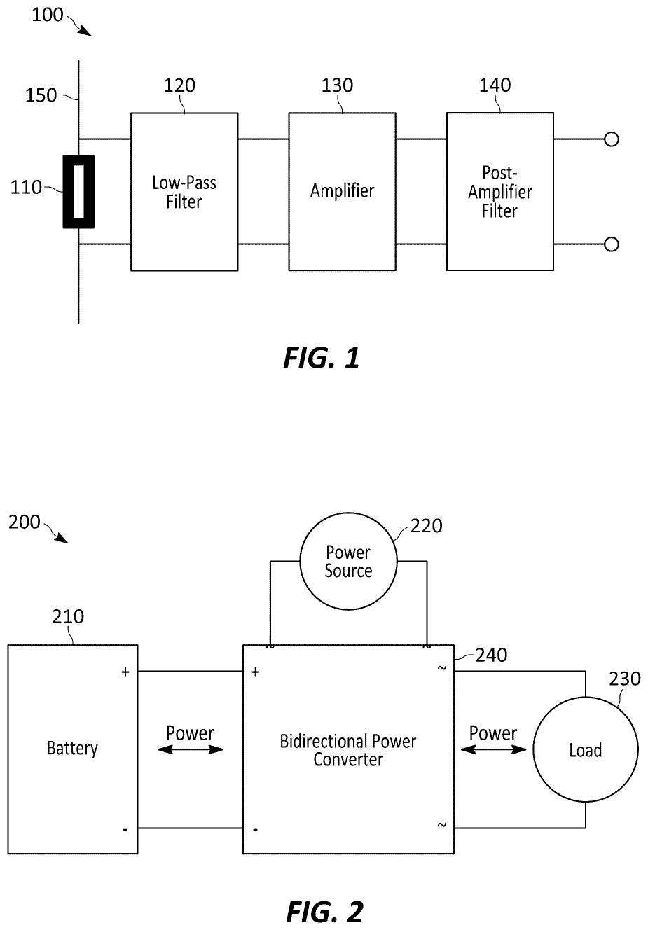

FIG. 1 illustrates a simplified block diagram of an example DC current measurement circuit 100. In the example illustrated, the DC current measurement circuit 100 includes a resistor 110, a low-pass filter (LPF) 120, an amplifier 130, and a post amplifier filter 140. The DC current measurement circuit 100 may include more of fewer components than those illustrated in FIG. 1. The resistor 110 is electrically connected in a current path 150 to monitor the current flow along the current path 150. The current flowing through the current path may include a DC component, an AC component, or both. In some examples, the DC component may be an undesired component for the device including the DC current measurement circuit 100. In one example, the resistor 110 is a current sense shunt resistor that may be provided as an integrated circuit or as part of an integrated circuit including two terminals, three terminals, or four terminals. In a two terminal shunt resistor, the two terminals are used for both connecting the shunt resistor in the current path 150 and for measuring the voltage drop across the current path 150. In a four terminal shunt resistor, two terminals are used for connecting the shunt resistor in the current path 150 and two other terminals are used for measuring the voltage drop across the current path 150. The resistor 110 is configured to convert the current flowing through the current path 150 into a voltage signal. That is, a voltage drop across the resistor 110 is proportional to the current flow through the current path 150 and this voltage drop may be measured as the voltage signal by a component connected across the resistor 110. The voltage signal indicates the voltage drop across the resistor 110 and is proportional to the current flow through the current path 150.

The LPF 120 is connected across the resistor 110 and receives the voltage signal. The LPF is connected in parallel to the resistor 110 and in parallel to the current path 150. The voltage signal may include both DC and AC components. The LPF 120 filters out the AC components and only allows the DC components to be output from the LPF 120. The LPF 120 may include a single stage or multiple stages (e.g., one or more stages) based on the desired filtering characteristics. The LPF 120 may be single ended or may be differential based on the desired filtering characteristics. Additionally, the LPF 120 may be passive or may be active based on the desired filtering characteristics. The voltage signal may be a differential signal such that the difference between two terminals indicates the level of voltage drop. The LPF 120 may also include a differential circuit such that the input is received at two input terminals and the output is provided at two output terminals to the amplifier 130.

The amplifier 130 is electrically connected to the output of the LPF 120 and receives a filtered voltage signal from the LPF 120. The gain of the resistor 110 and the LPF 120 is typically below 1. The amplifier 130 may use external power to amplify the voltage signal to facilitate current measurement. The amplifier 130 may be an inverting or non-inverting amplifier. The amplifier 130 may be an operational type, a discrete difference type, an integrated difference type, a fully differential type, an instrumentation type, an isolate type, or the like amplifier. In one example, the amplifier 130 is a difference type amplifier and includes additional circuitry (e.g., a level shifter circuit) to shift the output voltage present at zero resistor current to a nonzero value. This shifting of output voltage enables measurement of bipolar shunt resistor current with a difference amplifier supplied from a single positive voltage rail.

The post amplifier filter 140 is electrically connected to the output of the amplifier 130 and receives the amplified voltage signal from the amplifier 130. The post amplifier filter 140 offers additional filtering capabilities to the DC current measurement circuit 100. For example, the post amplifier filter 140 may supplement the LPF 120 to provide additional or redundant AC component filtering. The post amplifier filter 140 may also act to buffer a sampling capacitor in an analog to digital converter. The post amplifier filter 140 may further attenuate noise created by the amplifier, for example, when a chopper amplifier or a chopper stabilized amplifier is used for the amplifier 130. The post amplifier filter 140 may include a single stage or multiple stages based on the desired filtering characteristics. The post amplifier filter 140 may be single ended or may be differential based on the desired filtering characteristics. Additionally, the post amplifier filter 140 may be passive or may be active based on the desired filtering characteristics. In some examples, the post amplifier filter 140 may not be needed as the LPF 120 may provide sufficient filtering of undesired signals.

The amplifier 130 or the post amplifier filter 140 (when used) outputs a DC current measurement signal. A controller of an electronic device including the DC current measurement circuit 100 may receive the DC current measurement signal and determine the magnitude of current flow through the current path based on the DC current measurement signal. In some examples, an analog-to-digital converter may be connected between the post amplifier filter 140 and the controller to convert the DC current measurement signal to a digital signal for the controller. In other examples, the controller may include an analog-to-digital converter and the DC current measurement signal may be provided directly to the analog-to-digital converter pin of the controller. The inclusion of the filtering components, for example, the LPF 120 provided between the resistor 110 and the amplifier 130 enables the controller to accurately measure the typically small DC component of currents with significant AC content. As used herein, a controller that determines the DC component of the current based on the DC current measurement signal may determine the DC component directly from the output of the amplifier 130 or from the DC current measurement signal that is passed through other circuitry, e.g., the post amplifier filter, the analog-to-digital converter, or the like to condition the DC current measurement signal to be input to the controller.

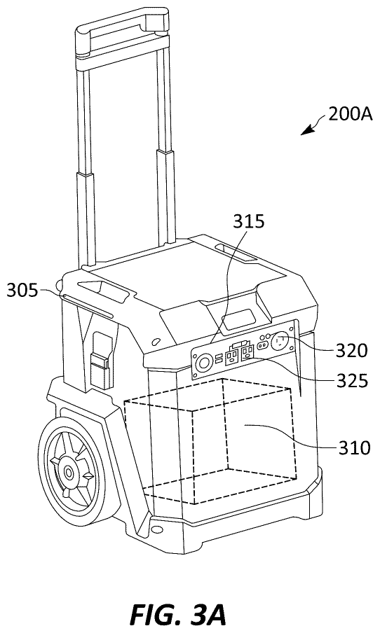

FIG. 2 illustrates a simplified block diagram of an electronic device 200 including the DC current measurement circuit 100. The electronic device 200 includes a battery system 210, a power source 220, a load 230, and a bidirectional converter 240. The electronic device may include more of fewer components than those illustrated in FIG. 2. The bidirectional converter 240 is electrically connected between the battery system 210, the power source 220, and the load 230. The bidirectional converter 240 may be configured to convert DC to DC, DC to AC, AC to DC or AC to AC. For example, the bidirectional converter 240 converts DC power from the battery system 210 to AC power or DC power at a different level for the load 230 and converts AC power or DC power from the power source 220 to DC power at a suitable level to charge the battery system 210.

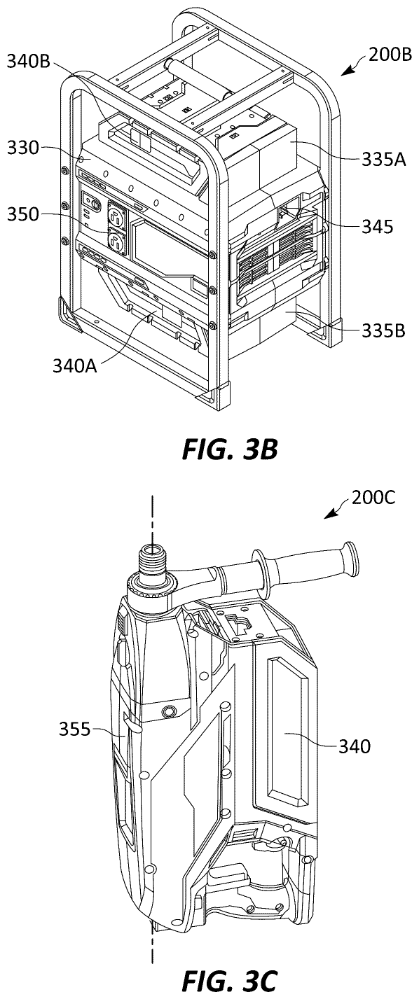

FIG. 3A illustrates an example electronic device 200 in the form of a portable power source 200A. The portable power source 200A includes a housing 305 for housing an internal battery module 310. The housing 305 also includes an input/output panel 315. The input/output panel 315 includes a power input 320 and a power outlet 325. The power outlet 325 is for example, an AC outlet for powering AC electronic devices or a DC outlet (e.g., USC-C outlet) for powering DC electronic devices. The internal battery module 310 corresponds to the battery system 210, the power input 320 corresponds to the power source 220, and the power outlet 325 corresponds to the load 230 of FIG. 2. The bidirectional converter 240 is coupled between the internal battery module 310, the power input 320, and the power outlet 325. The bidirectional converter 240 converts DC power from the internal battery module 310 to AC power or DC power for the power outlet 325. The bidirectional converter 240 also converts the AC power or DC power from the power input 320 to DC power at a suitable level for charging the internal battery module 310. The portable power source 200A may include additional components other than those described and illustrated herein. For example, the portable power source 200A may include additional power outlets 325 (e.g., both AC and DC), a display, and the like.

FIG. 3B illustrates an example electronic device 200 in the form of a portable power source 200B. The portable power source 200B includes a housing 330 having a first battery interface 335A and a second battery interface 335B. The first battery interface 335A and the second battery interface 335B are configured to receive a first removable power tool battery pack 340A and a second removable power tool battery pack 340B respectively. The first removable power tool battery pack 340A and the second removable power tool battery pack 340B, referred singularly as a removable power tool battery pack 340, are for example, lithium-ion power tool battery packs having a nominal voltage of 12 Volts, 18 Volts, 24 Volts, 36 Volts, 54 Volts, 72 Volts, 90 Volts, 108 Volts, or the like. The removable power tool battery pack 340 may be used to power cordless indoor and outdoor power tools. The portable power source 200B also includes a power input 345 and a power outlet 350. The power outlet 350 is for example, an AC outlet for power AC electronic devices or a DC outlet (e.g., USC-C outlet) for powering DC electronic devices. The removable power tool battery packs 340 correspond to the battery system 210, the power input 345 corresponds to the power source 220, and the power outlet 350 corresponds to the load 230. The bidirectional converter 240 is coupled between the removable power tool battery packs 340, the power input 345, and the power outlet 350. The bidirectional converter 240 converts DC power from the removable power tool battery packs 340 to AC power or DC power for the power outlet 250. The bidirectional converter 240 also converts the AC power or DC power from the power input 345 to DC power at a suitable level for charging the removable power tool battery packs 340. The portable power source 200B may include additional components other than those described and illustrated herein. For example, the portable power source 200B may include additional power outlets 350 (e.g., both AC and DC), a display, and the like.

FIG. 3C illustrates an example electronic device 200 in the form of a power tool 200C. In the example illustrated, the power tool 200C is a handheld core drill. The power tool 200C may include a different type of indoor and outdoor, handheld or mounted, power tool, for example, drill/drivers, saws, hammer drills, lighting equipment, grinders, or the like. The power tool 200C includes a housing 355 that houses a motor (e.g., a brushless direct current (BLDC) motor) and receives a removable power tool battery pack 340. The removable power tool battery pack 340 corresponds to the battery system 210 and the motor corresponds to the load 230. The bidirectional converter 240 is coupled between the removable power tool battery pack 340 and the motor. The bidirectional converter 240 converts DC power from the removable power tool battery pack 340 to AC power (e.g., for BLDC motor) or DC power (e.g., DC motor) for the motor. In some examples, the power tool 200C may further include a power cord to receive AC power. In these examples, the bidirectional converter 240 also converts the AC power from the power input or from the motor to DC power for charging the removable power tool battery pack 340. The power tool 300C may include additional components other than those described and illustrated herein.

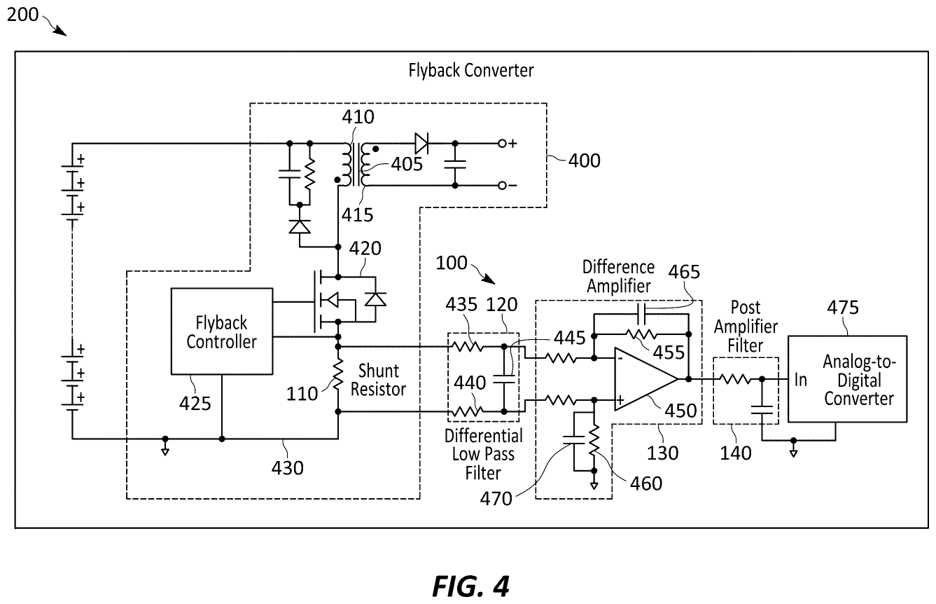

FIG. 4 illustrates an example embodiment of a flyback converter 400 that may be used in the electronic device 200. The flyback converter 400 is connected to the battery system 210 to boost or buck the voltage from the battery system 210. The flyback converter 400 includes a transformer 405 having a primary winding 410 and a secondary winding 415. In one example, the transformer 405 is a coupled inductor. The primary winding 410 is electrically connected to the battery system 210 using a switch 420. The switch 420 may include a solid-state switch, for example, a metal oxide semiconductor field effect transistor (MOSFET), a wide bandgap semiconductor FET, a bipolar junction transistor (BJT), or the like. The secondary winding 415 provides the converted output, for example, to the load 230 or to an intermediate circuit (e.g., an inverter).

The flyback converter 400 also includes a flyback controller 425 to control the switch 420. The flyback controller 425 provides control signals (e.g., at an output pin) to the gate of the switch 420 to turn the switch 420 on or off. The flyback controller 425 controls the switch 420 to convert the DC power at a first voltage from the battery system 210 to DC power at a second voltage provided at the output of the flyback converter 400.

The DC current measurement circuit 100 is connected in a current path 430 between the battery system 210 and the primary winding 410 of the flyback converter 400. In the example illustrated, the resistor 110 is connected in the current path 430. The flyback controller 425 includes a current sense pin CS (e.g., input pin) to receive an output from the resistor 110. The flyback controller 425 measures the current using the current sense pin CS and controls the switch 420 based on the measured current. In one example, the flyback controller 425 implements a peak current mode control principle to control the switch 420 based on the current detected at the current sense pin CS. In other example, the flyback controller 425 may implement a different control principle to control the switch 420. The same resistor 110 is shared between the DC current measurement circuit 100 and the current sense pin CS of the flyback controller 425. The resistor 110 provides primary peak current measurement to the flyback controller 425 through the current sense pin CS. The resistor 110 also converts the current drawn by the flyback converter 400 from the battery system 210 into a voltage for use by the DC current measurement circuit 100.

In the example illustrated in FIG. 4, the LPF 120 is implemented as a passive single stage, differential type low-pass filter including two resistors 435, 440 and a capacitor 445. The amplifier 130 is implemented as a difference amplifier constructed from an operational amplifier 450, two resistors 455, 460, and two capacitors 465, 470. In some examples, the two capacitors 465, 470 may be removed. The post amplifier filter 140 is implemented as a single stage, single ended, passive RC (resistor-capacitor) filter. In the example illustrated in FIG. 4, the DC current measurement circuit 100 also includes an analog-to-digital converter 475 coupled to the output of the post amplifier filter 140. The analog-to-digital converter 475 converts the analog DC current measurement signal from the amplifier 130 to a digital value for use by a controller (e.g., second controller) of, for example, a battery management system, the battery system 210, or the like. The DC current measurement circuit 100 is used in the flyback converter 400 to measure the average DC current that the flyback converter 400 draws from the battery system 210. This average DC current measurement can be used to track how quickly the battery is charging or discharging, a technique known as coulomb counting. This information can be used to model the battery system's 100 state of charge and state of health. For example, the second controller uses the measured DC component of the current to determine the state of charge of the battery system 210 and/or the state of health of the battery system 210 using a look-up table stored in a memory of the second controller. In some examples, the analog-to-digital converter 475 may be a part of (e.g., a component of) the second controller.

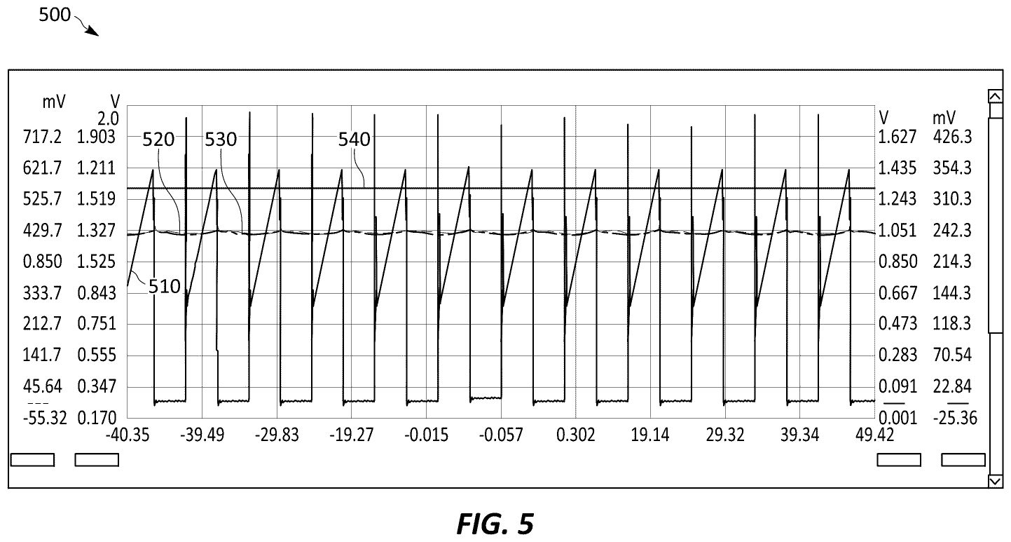

FIG. 5 illustrates a graph 500 showing the output of each component of the DC current measurement circuit 100 when used with the flyback converter 400. A first trace 510 of the graph 500 shows the voltage signal, which is the output of the resistor 110. As can be seen, there is signification switching noise resembling AC component from the switch 420 in the voltage signal. A second trace 520 of the graph 500 shows the voltage signal after passing through the LPF 120. The filtered voltage signal does not include the switching noise and provides an average of the DC current flowing through the current path 430. A third trace 530 of the graph 500 shows the amplified voltage signal from the amplifier 130. The voltage signal is amplified to a level sufficient for detection by a controller. A fourth trace 540 of the graph 500 shows the measurement signal after the amplified voltage signal passes through the post amplifier filter 140. AC components are further attenuated from the voltage signal when the voltage signal passes through the post amplifier filter 140 resulting in the measurement signal. The DC current measurement circuit 100 therefore provides accurate DC current measurement when significant AC components or AC like noise is present in the current signal.

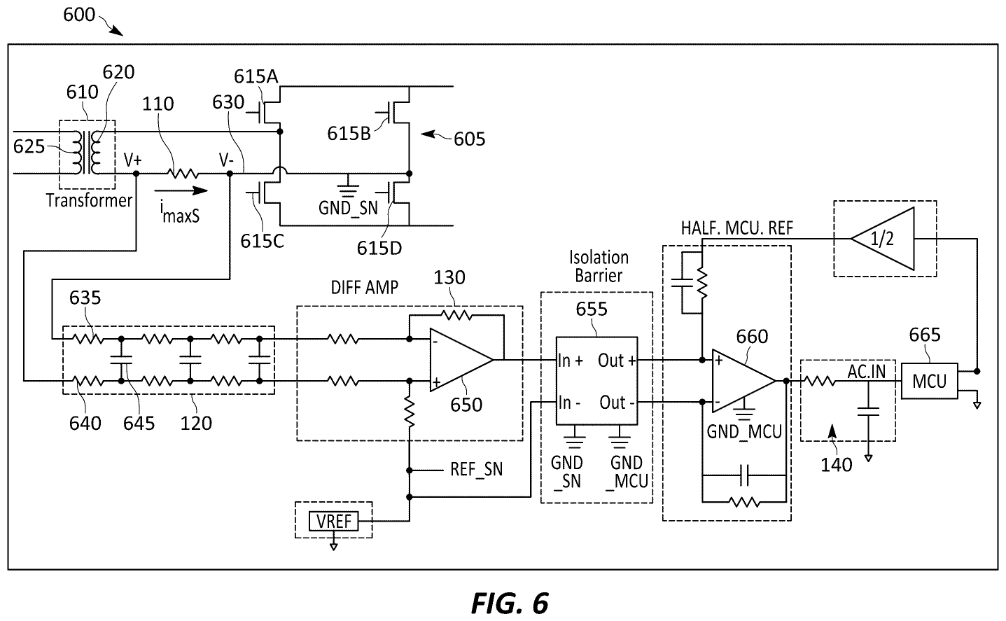

FIG. 6 illustrates an example embodiment of a DC-DC converter 600 that may be used in the electronic device 200. In the example illustrated, the DC-DC converter 600 includes a dual active bridge topology having a full bridge 605 (e.g., one or more H-bridge topologies) and a high frequency transformer 610. The full bridge 605 includes two high-side switches 615A, 615B and two low-side switches 615C, 615D. The switches 615 are, for example, MOSFETs, wide bandgap semiconductor FETs, BJTs, or the like. The input of the full bridge 605 may be connected to the battery system 210. The high frequency transformer 610 includes a primary winding 620 and a secondary winding 625. The output of the full bridge 605 is provided to the primary winding 620. The secondary winding 625 provides the converted output, for example, to the load 230 or to an intermediate circuit (e.g., an inverter). In other examples, the DC-DC converter 600 may be a switching converter have different H-bridge topologies.

In the example illustrated, the DC current measurement circuit 100 is connected in a current path 630 on the primary winding 620 side of the high frequency transformer 610. In other examples, the DC current measurement circuit 100 may be connected in a current path on the secondary winding 625 side of the high frequency transformer 610. In the example illustrated, the resistor 110 is connected in the current path 630. The resistor 110 converts the current through the primary winding 620 into a voltage for use by the DC current measurement circuit 100. The resistor 110 can be composed of one or more shunt resistors and converts the current through the transformer winding into a voltage for use by the DC current measurement circuit 100.

In the example illustrated in FIG. 6, the LPF 120 is implemented as a passive, three-stage, differential type low-pass filter including two resistors 635, 640 and a capacitor 645 per stage. The LPF 120 is configured to heavily attenuate the AC component of the voltage signal and allow the DC component to be amplified and measured. The amplifier 130 is implemented as a series of amplifiers including a high-gain differential amplifier 650, an isolation amplifier 655, and a differential to single-ended amplifier 660. The high-gain differential amplifier 650 is optimized for sensing voltage across the resistor 110. The isolation amplifier 655 provides isolation (e.g., galvanic isolation) between different ground references. The differential to single-ended amplifier 660 converts the differential output of the isolation amplifier to a single-ended output suitable to be provided to a controller pin. The differential to single-ended amplifier 660 may be constructed out of an operational-amplifier (op-amp) circuit and can include capacitors in the feedback network to further attenuate the AC component of the voltage signal via filtering.

The post amplifier filter 140 is implemented as a single stage, single ended, passive RC (resistor-capacitor) filter. In the example illustrated in FIG. 6, the electronic device 200 also includes a microcontroller unit (MCU) 665 that receives the single-ended output from the differential to single-ended amplifier 660. The single-ended output is received at an analog-to-digital converter pin ADC_IN of the MCU 665. The post amplifier filter 140 further attenuates any remaining AC component of the measured signal prior to being read by the analog-to-digital converter pin ADC_IN. The DC current measurement circuit 100 is used in the DC-DC converter 600 to measure the DC bias current in the winding of a large, high frequency transformer. The DC bias current may be measured as part of an active flux balancing strategy, where control logic can be used to actively limit the DC bias current through the winding of a transformer. The active flux balancing strategy can be used to prevent or reduce damage to the DC-DC converter 600 from DC bias current that may pass through the transformer 610.

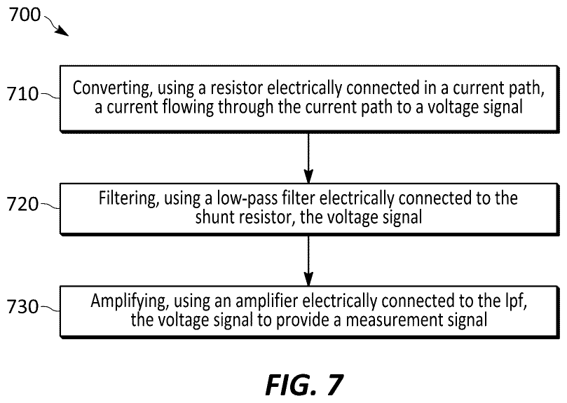

FIG. 7 illustrates a flowchart of an example method 700 for DC current measurement using the DC current measurement circuit 100. In the example illustrated, the method 700 includes converting, using the resistor 110 electrically connected in the current path 150, a current flowing through the current path 150 to a voltage signal (at block 710). The resistor 110 is, for example, a shunt resistor that is used for current detection and converts current flowing through the resistor 110 to a voltage signal to facilitate current measurement. The voltage signal indicates the voltage drop across the resistor 110 caused by the current flowing through the current path 150.

The method 700 includes filtering, using the LPF 120 electrically connected to the resistor 110, the voltage signal (at block 720). The LPF 120 receives the voltage signal from the resistor 110. The LPF 120 may include an RC (resistor-capacitor) circuit to filter out any AC component from the voltage signal. The LPF 120 may include multiple stages of filtering to adjust the level of attenuation.

The method 700 includes amplifying, using the amplifier 130 electrically connected to the LPF 120, the voltage signal to provide a measurement signal (at block 730). The amplifier 130 amplifies the voltage to a level suitable for detection by, for example, a controller or a control circuit. The measurement signal may be converted to a digital signal by an analog-to-digital converter before being provided to a controller. In some examples, the controller may include an analog-to-digital converter built in and can receive the measurement signal directly from the DC current measurement circuit 100.

Although the disclosure has been described in detail with reference to certain preferred embodiments, variations and modifications exist within the scope and spirit of one or more independent aspects of the disclosure as described. Various features and advantages are set forth in the following claims.

What is claimed is:

1. A direct-current (DC) current measurement circuit comprising:
a shunt resistor electrically connected in a current path, wherein a current flowing through the current path includes an alternating-current (AC) component;
a low-pass filter (LPF) electrically connected across the shunt resistor and configured to filter a voltage signal across the shunt resistor and output a filtered voltage signal; and
an amplifier electrically connected to the LPF and configured to receive the filtered voltage signal and output a measurement signal, wherein the measurement signal provides a measurement of a DC component of the current.

2. The DC current measurement circuit of claim 1, wherein the LPF is a passive, differential type filter with one or more stages.

3. The DC current measurement circuit of claim 1, wherein the LPF is a passive, three-stage, differential type filter.

4. The DC current measurement circuit of claim 1, wherein the amplifier includes a difference type amplifier.

5. The DC current measurement circuit of claim 4, wherein the amplifier further includes:
an isolation amplifier electrically coupled to the difference type amplifier and configured to provide isolation between different ground references; and
a differential to single-ended amplifier electrically coupled to the isolation amplifier and configured to convert a differential output of the isolation amplifier to a single-ended output.

6. The DC current measurement circuit of claim 1, further comprising a controller configured to determine the DC component of the current flowing through the current path based on the measurement signal.

7. The DC current measurement circuit of claim 6, further comprising an analog to digital converter electrically coupled between the amplifier and the controller and configured to convert the measurement signal to a digital signal and provide the digital signal to the controller.

8. The DC current measurement circuit of claim 1, further comprising a post amplifier filter electrically coupled to the amplifier and configured to filter the measurement signal.

9. The DC current measurement circuit of claim 1, wherein the LPF is configured to filter the AC component of the current from the voltage signal.

10. An electronic device, comprising:
a power converter electrically connected between a battery system and a load; and
a direct-current (DC) current measurement circuit electrically connected in a current path of the power converter and including
a resistor electrically connected in the current path, wherein a current flowing through the current path includes an alternating-current (AC) component;
a low-pass filter (LPF) electrically connected across the resistor and configured to filter a voltage signal across the resistor and output a filtered voltage signal; and
an amplifier electrically connected to the LPF and configured to amplify the filtered voltage signal and output a measurement signal.

11. The electronic device of claim 10, wherein the power converter is a flyback converter.

12. The electronic device of claim 11, wherein the flyback converter includes a switch, the electronic device further comprising:
a flyback converter controller including an input pin connected to a terminal of the resistor and an output pin connected to the switch, wherein the flyback converter controller configured to
determine a measure of the current based on a signal at the input pin, and
provide a control signal at the output pin to control the switch based on the measure of the current; and
a second controller configured to
determine, using the DC current measurement circuit, a DC component of the current, and
determine one selected from a group consisting of a state of charge of the battery system and a state of health of the battery system based on the DC component of the current.

13. The electronic device of claim 10, wherein the power converter is a DC-DC converter including a high frequency transformer and one or more H-bridge topologies, wherein the current path provides current to a winding of the high frequency transformer from the dual active bridge.

14. The electronic device of claim 13, further comprising:
an isolating amplifier including an input side and an output side and configured to provide galvanic isolation between the input side and the output side, wherein the input side connected to the amplifier to receive the measurement signal and wherein the output side provides a differential output corresponding to the measurement signal;
a differential to single-ended amplifier connected to the output side of the isolating amplifier and configured to convert the differential output to a single-ended output; and
a microcontroller unit including a digital pin configured to receive the single-ended output from the differential to single-ended amplifier.

15. The electronic device of claim 12, wherein the LPF is a passive, three-stage, differential type filter.

16. A portable power source comprising:
a battery system;
a power converter electrically connected to the battery system; and
a direct-current (DC) current measurement circuit electrically connected in a current path of the power converter and including
a resistor electrically connected in the current path, wherein a current flowing through the current path includes an alternating-current (AC) component;
a low-pass filter (LPF) electrically connected across the resistor and configured to filter a voltage signal across the resistor and output a filtered voltage signal; and
an amplifier electrically connected to the LPF and configured to amplify the filtered voltage signal and output a measurement signal.

17. The portable power source of claim 16, wherein the power converter is a flyback converter including a switch, the portable power source further comprising:
a flyback converter controller including an input pin connected to a terminal of the resistor and an output pin connected to the switch, wherein flyback converter controller configured to
determine a measure of the current based on a signal at the input pin, and
provide a control signal at the output pin to control the switch based on the measure of the current; and
a second controller configured to
determine, using the DC current measurement circuit, a DC component of the current, and
determine one selected from a group consisting of a state of charge of the battery system and a state of health of the battery system based on the DC component of the current.

18. The portable power source of claim 17, wherein the DC measurement circuit further comprises:
an analog-to-digital converter electrically connected to the amplifier and configured to convert the measurement signal to a digital signal at an output of the analog-to-digital converter, wherein the output of the analog-to-digital converter is connected to an input pin of the second controller.

19. The portable power source of claim 16, wherein the power converter is a DC-DC converter including a high frequency transformer and one or more H-bridge topologies, wherein the current path provides the current to a winding of the high frequency transformer from the dual active bridge, the portable power source further comprising:
an isolating amplifier including an input side and an output side and configured to provide galvanic isolation between the input side and the output side, wherein the input side connected to the amplifier to receive the measurement signal and wherein the output side provides a differential output corresponding to the measurement signal;
a differential to single-ended amplifier connected to the output side of the isolating amplifier and configured to convert the differential output to a single-ended output; and
a microcontroller unit including a digital pin configured to receive the single-ended output from the differential to single-ended amplifier.

20. The portable power source of claim 16, wherein the LPF is a passive, three-stage, differential type filter.
